(19) United States
(12) Patent Application Publication
(10) Pub. No.: US 2004/0211972 A1
(43) Pub. Date: Oct. 28, 2004

(54) Flip-chip light emitting diode

(75) Inventors: Shawn X. Du, Macedonia, OH (US); Ivan Eliashevich, Maplewood, NJ (US)

Correspondence Address: Scott A. McCollister, Esq., Fay, Sharpe, Fagan, Minnich & McKee, LLP, Seventh Floor, 1100 Superior Avenue, Cleveland, OH, 44114-2579, US

(73) Assignee: GELcore, LLC

(21) Appl. No.: 10/828,576

(22) Filed: Apr. 21, 2004

Related U.S. Application Data
(60) Provisional application No. 60/464,512, filed on Apr. 22, 2003.

(51) Int. Cl. H01L 33/00

(52) U.S. Cl. 257/99

(57) ABSTRACT

In a method of manufacturing a flip-chip light emitting diode, semiconductor layers (14, 16, 16′, 18, 18′, 20, 20′) that define a light emitting electrical junction (18, 18′) are epitaxially deposited on a principle surface of an epitaxy substrate (12, 12′). A light-emitting device mesa (24, 24′) is formed from the epitaxially deposited semiconductor layers. A first electrode (30, 30′, 54) is formed on a portion of the device mesa distal from the epitaxy substrate. The first electrode electrically contacts the device mesa. A second electrode (32, 32′, 56) is disposed on the principle surface of the substrate. First and second electrodes are flip-chip bonded to bonding pads (40, 40′, 42, 42′). The epitaxy substrate is removed. An electrically conductive, light-transmissive window layer (14, 14′) is arranged over the device mesa and the second electrode. The window layer forms an electrical connection between the device mesa and the second electrode.

This application claims the benefit of provisional application Ser. No. 60/464,512 filed on Apr. 22, 2003.

### BACKGROUND

The present invention relates to the lighting arts. It especially relates to phosphide-based high power flip chip light emitting diodes for signaling and lighting applications, and will be described with particular reference thereto. However, the invention will also find application in conjunction with other types of flip-chip light emitting diodes and with other types of optoelectronic devices.

Light emitting diodes are increasingly being employed in outdoor displays and signal lights, indoor illumination, and other applications. High brightness AlInGaP light emitting diodes provide light in the red to amber spectral range. A mature epitaxial growth technology base exists for generating high-quality AlInGaP layers on GaAs substrates. Light emitting devices are typically fabricated by forming a mesa and depositing front and back electrodes on the topmost AlInGaP layer and on the conductive GaAs substrate, respectively. Alternatively, two front-side contacts can be employed.

Heretofore, AlInGaP light emitting diodes have not typically employed a flip-chip arrangement, such as is well-known for GaN-based ultraviolet and blue light emitting diodes. A reason for this is that unlike the transparent sapphire epitaxy substrates generally used for GaN epitaxy, GaAs substrates used in AlInGaP epitaxy are absorbing for red and amber light.

The present invention contemplates an improved apparatus and method that overcomes the above-mentioned limitations and others.

### BRIEF SUMMARY

According to one aspect, a method of manufacturing a light emitting diode is provided. A plurality of semiconductor layers are deposited on a deposition substrate. At least some of the deposited semiconductor layers are removed from a selected trench region of the deposition substrate to define a light-emissive mesa. An electrode is formed on the mesa. The mesa is flip-chip bonded to a first electrical bonding pad of a thermally conductive support. The deposition substrate is removed.

According to another aspect, a flip-chip light emitting diode is disclosed. A thermally conductive support structure includes first and second electrical pads arranged on a surface of the support structure for delivering electrical power. A plurality of light-generating semiconductor layers define a light-emissive mesa electrically contacting the first electrical pad. A window layer is disposed over the light-emissive mesa and the second electrical pad. The window layer electrically contacts the second electrical pad. The window layer is light-transmissive with respect to light generated by the light-generating semiconductor layers. The window layer further is electrically conductive to define a current-spreading electrical path between the light-emissive mesa and the second electrical pad.

According to yet another aspect, a method of manufacturing a flip-chip light emitting diode is provided. Semiconductor layers that define a light emitting electrical junction are epitaxially deposited on a principle surface of an epitaxy substrate. A light-emitting device mesa is formed from the epitaxially deposited semiconductor layers. A first electrode is formed on a portion of the device mesa distal from the epitaxy substrate. The first electrode electrically contacts the device mesa. A second electrode is disposed on the principle surface of the substrate. First and second electrodes are flip-chip bonded to bonding pads. The epitaxy substrate is removed. An electrically conductive, light-transmissive window layer is arranged over the device mesa and the second electrode. The window layer forms an electrical connection between the device mesa and the second electrode.

Numerous advantages and benefits of the present invention will become apparent to those of ordinary skill in the art upon reading and understanding the present specification.

### BRIEF DESCRIPTION OF THE DRAWINGS

The invention may take form in various components and arrangements of components, and in various process operations and arrangements of process operations. The drawings are only for purposes of illustrating preferred embodiments and are not to be construed as limiting the invention.

FIG. 1 shows a side view of an AlInGaP light emitting diode prior to flip-chip bonding.

FIG. 2 shows a side view of the AlInGaP light emitting diode epitaxial structure of FIG. 1 flip-chip bonded to a support, with the epitaxy substrate removed.

FIG. 3A shows a top view of the p-type and n-type electrodes of the AlInGaP light emitting diode epitaxial structure of FIG. 1.

FIG. 3B shows a top view of alternative p-type and n-type electrodes with a larger p-type electrode-to-n-type electrode area ratio.

FIG. 4 shows a side view of another AlInGaP light emitting diode epitaxial structure, flip-chip bonded to a support.

FIG. 5 shows a side view of the flip-chip bonded AlInGaP light emitting diode epitaxial structure of FIG. 4, with the epitaxy substrate removed and a window layer deposited.

It is to be appreciated that the FIGURES are for exemplary purposes only and are not drawn to scale.

### DETAILED DESCRIPTION OF PREFERRED EMBODIMENTS

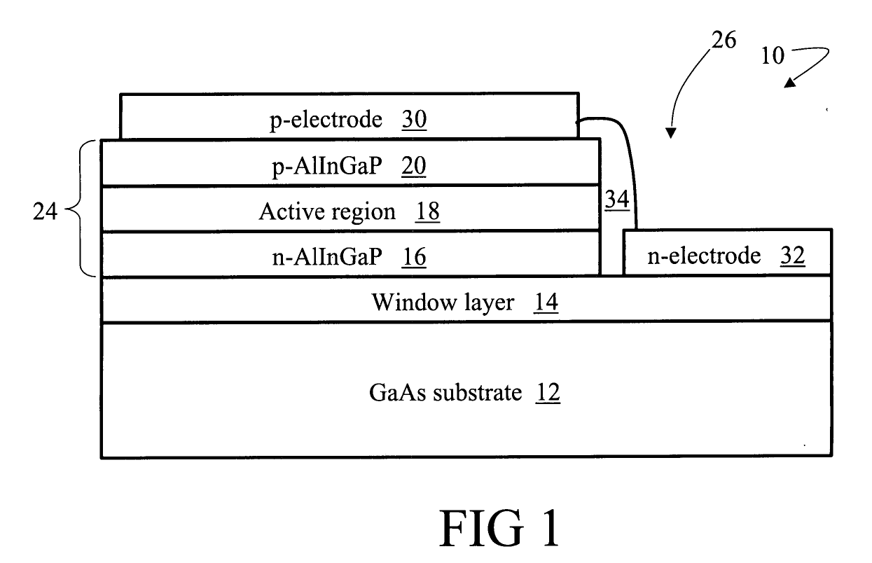

With reference to FIG. 1, an AlInGaP light emitting diode epitaxial structure 10 includes a GaAs epitaxy substrate 12, a window layer 14 epitaxially deposited on the GaAs substrate 12, and a plurality of light-emitting semiconductor layers 16, 18, 20 epitaxially deposited on the window layer 14. In the exemplary illustrated device structure 10, the light-emitting semiconductor layers 16, 18, 20 include an n-type AlInGaP layer 16 and a p-type AlInGaP layer 20, with an active region 18 of low-doped (typically not intentionally doped) AlInGaP disposed therebetween. In a preferred embodiment, the semiconductor layers 16, 18, 20 are epitaxially deposited using metalorganic chemical vapor deposition (also known as organometallic vapor phase epitaxy or the like). In another suitable embodiment, molecular beam epitaxy is used to deposit semiconductor layers 16, 18, 20.

In operation, holes and electrons are supplied to the active region 18 that is arranged at the electrical junction of the p-type and n-type layers 16, 20. Electron-hole pairs radiatively recombine in the active region 18 to emit light. The spectral distribution of emitted light is generally determined by characteristics of the active region 18, such as the composition and bandgap of the AlInGaP layer 18.

The illustrated light-emitting semiconductor layers 16, 18, 20 are exemplary only. Those skilled in the art can readily include other or additional semiconductor layers for achieving specific light emission characteristics. For example, the active region can include quantum wells. Additional heavily doped p- and/or n-type layers can be incorporated to improving electrical current injection into the active region 18. The alloy compositions of the AlInGaP layers are selected to obtain desired bandgap, optical, and other material characteristics while remaining substantially lattice-matched to GaAs. However, as is known in the art some lattice mismatch can be included, especially in thinner layers such as active region quantum wells, to produce coherently strained layers. Incorporation of one or more strain-relaxed lattice-mismatched layers is also contemplated. However, in view of material degradation that typically occurs due to defects introduced by strain relaxation, lattice-matched or coherently strained layers are generally preferred.

The window layer 14 is selected to be substantially electrically conductive and light-transmissive for light generated by the light-emitting semiconductor layers 16, 18, 20. Unless the semiconductor layers 16, 18, 20 are intended to be strain-relaxed, the window layer 14 should also be lattice-matched to the GaAs substrate. For the exemplary AlInGaP light emitting diode structure, suitable materials for the window layer 14 include ternary AlGaAs, which is lattice-matched to GaAs for most compositions, and wide-bandgap AlInGaP materials such as AlInP. To provide adequate light extraction and electrical current spreading, the window layer 14 preferably has a thickness of at least two microns.

A device mesa 24 is defined by selectively removing the semiconductor layers 16, 18, 20 in selected trench regions 26 of the substrate 12. In a preferred embodiment, the trench regions 26 are formed photolithographically. A p-type electrode 30 is formed on a surface of the device mesa 24 distal from the substrate 12. An n-type electrode 32 is disposed on the substrate 12 by forming the electrode 32 on the window layer 14 in the trench region 26. Optionally, an insulating layer 34 is deposited between the device mesa 24 and the n-type electrode 32 to ensure substantial electrical isolation therebetween. The electrodes 30, 32 and optional insulator 34 are suitably formed by evaporation, sputtering, or otherwise depositing the metal or insulator material, in conjunction with photolithographic processing. The electrodes 30, 32 can be formed of the same or different material. Typically, each electrode includes a metal layer stack designed to provide an approximately ohmic contact with the semiconductor 20 or the window layer 14.

Those skilled in the art recognize that the AlInGaP light emitting diode epitaxial structure 10 is similar to a conventional AlInGaP light emitting diode epitaxial structure, except that the window layer 14 is arranged adjacent to the epitaxy substrate 12. In contrast, in a conventional AlInGaP light emitting diode epitaxial structure the window layer, if present, is arranged as a topmost layer or a nearly topmost layer of the epitaxial semiconductor layer stack. That is, in a conventional AlInGaP light emitting diode epitaxial structure, the window is arranged in the semiconductor stack distal from the substrate, rather than adjacent thereto.

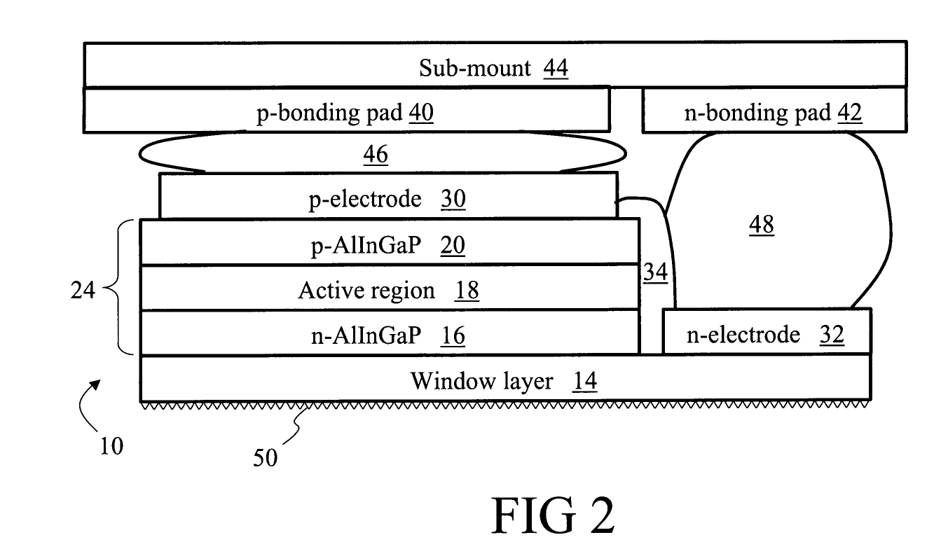

With reference to FIG. 2, the AlInGaP light emitting diode epitaxial structure 10 is flip-chip bonded to p-type and n-type electrical bonding pads 40, 42 of a thermally conductive sub-mount 44 via solder bumps 46, 48 respectively. After flip-chip bonding, the GaAs substrate 12 is removed by chemical etching, plasma etching, or another suitable technique to expose the window layer 14. Preferably, the window layer 14 acts as an etch stop. For example, certain phosphoric acid/hydrogen peroxide aqueous solutions are known to be highly selective for etching GaAs over phosphide-based semiconductors. Rather than or in conjunction with chemical or plasma etching, mechanical polishing can be used to remove or thin the epitaxy substrate 12.

After substrate removal, the exposed surface 50 of the window layer 14 is optionally roughened, patterned, or otherwise modified to further improve light extraction. Light extraction can be improved by forming a Fresnel lensing pattern on the surface 50, or by applying an epoxy coating, plastic coating, refractive index matching coating after removal of the epitaxy substrate 12. A micro-lens can also be bonded to the exposed surface 50. Optionally, the device mesa 24 can additionally include a distributed Bragg reflector or other reflective layer or layers (not shown) disposed between the p-type AlInGaP layer 20 and the p-type electrode 30 during epitaxy to further increase reflectivity.

In operation, electrical bias applied at the electrical bonding pads 40, 42 energize the device through a current path (traced in the following from positive to negative) including: the p-type bonding pad 40; the solder bump 46; the p-type electrode 30; the device mesa 24; the current-spreading window layer 14; the n-type electrode 32; the solder bump 48; and the n-type bonding pad 42. Light emitted by the device mesa 24 passes out the window layer 14 via the surface 50 as the device light output. Light generally directed toward the p-type electrode 30 is reflected toward the window layer 14 and also contributes to the device light output through the surface 50.

To enable chip-scale package design, bonding pads 40, 42 for a plurality of light emitting diodes can be interconnected by printed circuitry on the sub-mount 44 or other support structure. Moreover, the support structure can include driving electronics connected to the light emitting diodes by the printed circuitry.

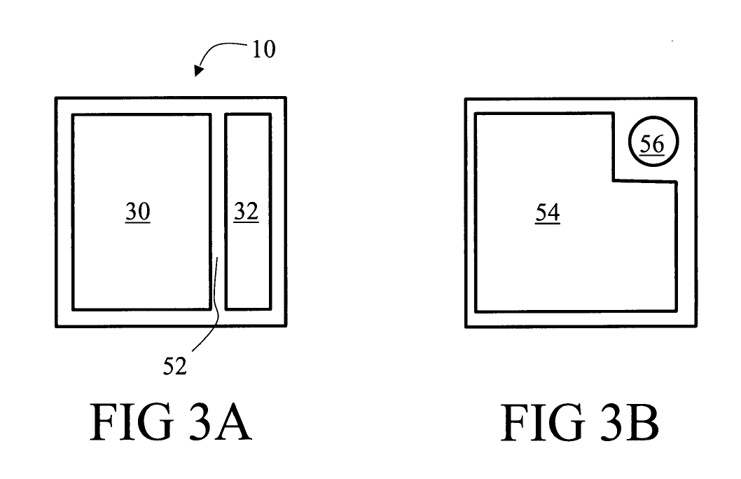

With reference to FIG. 3A, the electrodes 30, 32 are arranged with a gap 52 therebetween. However, other electrode configurations can also be employed, such as the configuration shown in FIG. 3B, in which a p-type electrode 54 is made larger compared with the electrode 30, while an n-type electrode 56 is made smaller. A large p-type electrode-to-n-type electrode area ratio is advantageous since the light emitting mesa underlies the p-type electrode. (However, it will be recognized that if the polarity of the mesa is reversed, so that the n-type electrode is on the mesa, then a large n-type electrode-to-p-type electrode area ratio is advantageous). The optimal electrode area ratio depends upon various factors including chip size, current spreading capability of the window layer, and the ohmic contact quality of the electrodes.

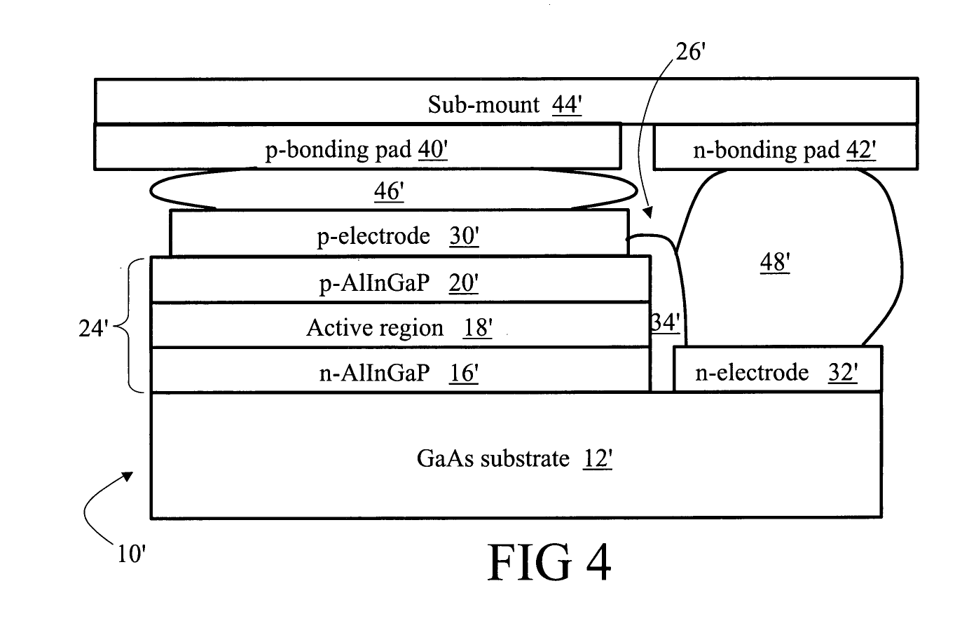

With reference to FIG. 4, another AlInGaP light emitting diode epitaxial structure 10′ includes a GaAs epitaxy substrate 12′ and a plurality of light-emitting semiconductor layers 16′, 18′, 20′ epitaxially deposited on the GaAs epitaxy substrate 12′. A device mesa 24′ is defined by selectively removing the semiconductor layers 16′, 18′, 20′ in selected trench regions 26′ of the substrate 12′. A p-type electrode 30′ is formed on a surface of the device mesa 24′ distal from the substrate 12′. An n-type electrode 32′ is disposed on the substrate 12′ by forming the electrode 32′ on the epitaxy substrate 12′ in the trench region 26′. Optionally, an insulating layer 34′ is deposited between the device mesa 24′ and the n-type electrode 32′ to ensure substantial electrical isolation therebetween.

It will be recognized that the epitaxial structure 10′ is generally similar to the epitaxial structure 10 of FIG. 1, except that the epitaxially grown window layer 14 of the epitaxial structure 10 is omitted. The epitaxial structure 10′ is flip-chip bonded to p-type and n-type electrical bonding pads 40′, 42′ of a thermally conductive sub-mount 44′ via solder bumps 46′, 48′ respectively.

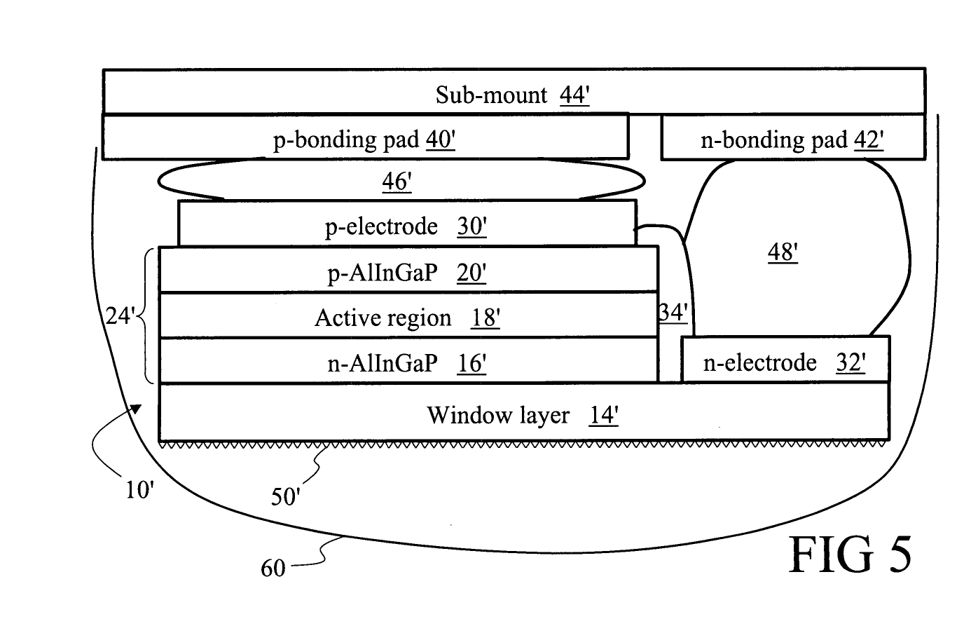

With reference to FIG. 5, after flip-chip bonding, the GaAs substrate 12′ is removed by chemical etching, plasma etching, or another suitable technique. Removal of the epitaxy substrate 12′ exposes the n-type AlInGaP layer 16′ and a surface of the n-type electrode 32′ where it had contacted the substrate 12′. Removal of the GaAs substrate 12′ effects a physical separation of the mesas 24′ at the trenches 26′. After removal of the epitaxy substrate 12′, a substantially electrically conductive and light-transmissive window layer 14′ is deposited over the n-type AlInGaP layer 16′ and the exposed surface of the n-type electrode 32′ to form an electrically conductive connection therebetween.

Because the window layer 14′ is deposited after epitaxial growth of the semiconductor layers 16′, 18′, 20′, the window layer 14′ is generally not epitaxial with respect to the semiconductor layers 16′, 18′, 20′. Rather, the window layer 14′ can be selected for preferred electrical and optical characteristics. Suitable materials for the window layer 14′ include sputtered indium tin oxide, GaP or AlGaAs grown by liquid phase epitaxy, or the like. The window layer 14′ is preferably at least two microns thick; hence, a fast deposition technique such as sputtering or liquid phase epitaxy is preferably employed. In contrast, the epitaxial window 14 of the embodiment of FIGS. 1 and 2 is grown along with semiconductor layers 16, 18, 20 by metalorganic chemical vapor deposition or molecular beam epitaxy, which are slower layer deposition techniques.

The electrodes 30′, 32′ are typically metal layer stacks optimized to provide approximately ohmic contact with the p-AlInGaP layer 20′ and the window layer 14′, respectively. Moreover, if the electrical characteristics of a direct junction between material of the window layer 14′ and material of the solder bump 48′ are sufficiently ohmic, the n-type electrode 32′ is optionally omitted.

A surface 50′ of the window layer 14′ is optionally roughened or patterned (for example with a Fresnel lens pattern) to further improve light extraction. Additionally, an encapsulant 60 can be included adjacent to the surface 50′ and surrounding the light emitting diode device to hermetically seal the light emitting diode and to improve light extraction. Similarly, a microlens or other light-coupling element can be bonded to the surface 50′ of the window layer 14′.

Although AlInGaP light emitting diodes have been illustrated, those skilled in the art can readily adapt these exemplary devices to the manufacture flip-chip bonded light emitting diodes in other materials systems that are grown on epitaxy substrates that substantially absorb the light output.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

What is claimed is:

1. A method of manufacturing a light emitting diode, the method including:
depositing a plurality of semiconductor layers on a deposition substrate;
removing at least some of the deposited semiconductor layers from a selected trench region of the deposition substrate to define a light-emissive mesa;
forming an electrode on the mesa;
flip-chip bonding the mesa to a first electrical bonding pad of a thermally conductive support; and
removing the deposition substrate.

2. The method as set forth in claim 1, further including:
subsequent to the removing of the deposition substrate, depositing a light-transmissive, electrically conductive window layer on a surface of the mesa opposite the electrode, the window layer extending laterally to electrically contact a second electrical bonding pad of the thermally conductive support to define an electrical path between the mesa and the second electrical bonding pad.

3. The method as set forth in claim 2, further including:
prior to the depositing of a window layer, depositing an insulating material between the second electrical bonding pad and the mesa, the window layer extending laterally over the insulating material.

4. The method as set forth in claim 2, wherein the depositing of a window layer includes:
depositing at least one window layer by liquid phase epitaxy.

5. The method as set forth in claim 2, wherein the depositing of a window layer includes:
non-epitaxially depositing at least one window layer.

6. The method as set forth in claim 1, wherein the removing of at least some of the deposited semiconductor layers to define a light-emissive mesa defines a plurality of mesas, and the removing of the deposition substrate effects a physical separation of the mesas wherein the mesas define a plurality of separated light emitting diode device dice in which each device die is flip-chip bonded to the thermally conductive support.

7. The method as set forth in claim 1, wherein the removing of at least some of the deposited semiconductor layers from a selected trench region includes retaining at least one semiconductor layer that is substantially electrically conductive in the trench region, and the flip chip bonding further includes:
flip-chip bonding a second electrical bonding pad to the retained semiconductor layer in the trench region, wherein the retained semiconductor layer defines an electrical path between the mesa and the second bonding pad.

8. The method as set forth in claim 7, further including:
prior to the flip chip-bonding, depositing an insulating material at least on sidewalls of the mesa.

9. The method as set forth in claim 7, wherein the deposition substrate is a GaAs substrate, the plurality of semiconductor layers include group III-phosphide layers, and the retained semiconductor layer includes a layer that contains aluminum.

10. A flip-chip light emitting diode including:
a thermally conductive support structure including first and second electrical pads arranged on a surface of the support structure for delivering electrical power;
a plurality of light-generating semiconductor layers defining a light-emissive mesa electrically contacting the first electrical pad; and
a window layer disposed over the light-emissive mesa and the second electrical pad, the window layer electrically contacting the second electrical pad, the window layer being light-transmissive with respect to light generated by the light-generating semiconductor layers, the window layer further being electrically conductive to define a current-spreading electrical path between the light-emissive mesa and the second electrical pad.

11. The flip chip light emitting diode as set forth in claim 10, further including:
an insulator disposed between the mesa and the second electrical pad and electrically isolating the mesa from the second electrical pad.

12. The flip chip light emitting diode as set forth in claim 10, wherein the window layer is not epitaxial with respect to the light-emissive mesa.

13. The flip chip light emitting diode as set forth in claim 10, wherein the window layer includes an indium tin oxide layer disposed over the light-emissive mesa and the second electrical pad.

14. The flip chip light emitting diode as set forth in claim 10, wherein the window layer has a thickness of at least 2 microns.

15. The flip chip light emitting diode as set forth in claim 10, wherein the light-generating semiconductor layers include epitaxially deposited layers.

16. The flip chip light emitting diode as set forth in claim 10, wherein the window layer directly contacts an encapsulant disposed over the window layer.

17. The flip chip light emitting diode as set forth in claim 10, wherein the window layer is exposed to air.

18. A method of manufacturing a flip-chip light emitting diode, the method including:
epitaxially depositing semiconductor layers that define a light emitting electrical junction on a principle surface of an epitaxy substrate;
forming a light-emitting device mesa from the epitaxially deposited semiconductor layers;
forming a first electrode on a portion of the device mesa distal from the epitaxy substrate, the first electrode electrically contacting the device mesa;
disposing a second electrode on the principle surface of the substrate;
flip-chip bonding first and second electrodes to bonding pads;
removing the epitaxy substrate; and
arranging an electrically conductive, light-transmissive window layer over the device mesa and the second electrode, the window layer forming an electrical connection between the device mesa and the second electrode.

19. The method as set forth in claim 18, wherein the arranging of the window layer includes:
depositing the window layer adjacent to the epitaxy substrate during the epitaxial depositing of the semiconductor layers.

20. The method as set forth in claim 19, wherein the disposing of a second electrode on the principle surface of the substrate includes:
forming the second electrode on the window layer, the second electrode electrically contacting the window layer.

21. The method as set forth in claim 19, wherein the removing of the epitaxy substrate includes:
etching the epitaxy substrate, wherein the window layer provides an etch stop for the chemical removing.

22. The method as set forth in claim 18, wherein the arranging of the window layer includes:
subsequent to the removing of the epitaxy substrate, depositing the window layer over the device mesa and the second electrode.

23. The method as set forth in claim 18, wherein the removing of the epitaxy substrate includes:
etching the epitaxy substrate using one of wet chemical etching and plasma etching.
